(19) United States
(12) Patent Application Publication
(10) Pub. No.: US 2004/0182319 A1
(43) Pub. Date: Sep. 23, 2004

(54) Inductively coupled plasma generation system with a parallel antenna array having evenly distributed power input and ground nodes

(76) Inventors: Harqkyun Kim, Cypress, CA (US); Yunju Ra, Irvine, CA (US)

Correspondence Address: William J. Benman, Suite 2740, 2049 Century Park East, Los Angeles, CA, 90067, US

(21) Appl. No.: 10/391,383

(22) Filed: Mar. 18, 2003

(51) Int. Cl. C23C 16/00

(52) U.S. Cl. 118/723 I

(57) ABSTRACT

An antenna adapted to apply uniform electromagnetic fields to a volume of gas and including radiating elements connected in parallel with evenly distributed input terminals for receiving electromagnetic energy into the antenna and output terminals for grounding. In the illustrative embodiment, the antenna has three radiating elements connected in parallel. Each radiating element is a conductor wound in a circular shape with the same diameter. Each radiating element is connected to the input terminal on one end and an output terminal on the other. The input terminal of the second element is 120° rotated counterclockwise from the first and the input terminal of the third is rotated by 120° counterclockwise from the second. The ground terminals of each radiating elements are located in the same manner as the input terminals. The inventive antenna affords a novel method for plasma processing a device including the steps of mounting the device within a chamber; and applying an electromagnetic field to the gas via an array of antenna elements disposed relative to the gas to generate a uniform distribution of the plasmas.

### BACKGROUND OF THE INVENTION

1. Field of the Invention

The present invention relates to plasma processing systems. More specifically, the present invention relates to plasma sources used for plasma etching, chemical vapor deposition, photo-resist stripping and other applications relating to semiconductor, flat panel display, printed circuit board and other fabrication processes.

2. Description of the Related Art

Plasmas sources capable of uniform coupling of electromagnetic energy to plasmas are needed for many plasma processes such as plasma etching, plasma enhanced chemical vapor deposition, physical vapor deposition, photo-resist stripping and surface treatments for many applications. Illustrative applications include silicon and compound semiconductor fabrication, flat panel display fabrication including active matrix liquid crystal display, plasma display panels, field emission displays etc. Additional applications include hard disk drive head and media manufacturing, micro-electromechanical system manufacturing and printed wiring board fabrication.

A plasma source typically includes a radio frequency antenna, a dielectric window and a volume of gas. An electric field from an impedance matched power supply is applied to the gas by the antenna through the dielectric tube. The application of the electric field to the gas generates two fields of interest with respect to plasma processing: time varying electromagnetic fields and capacitive electric fields. Free electrons gain energy by these electromagnetic fields and generate ions by collision with neutral gases, thereby generating plasmas. The inductive technique using a time varying electromagnetic field is known to be more efficient in the production of plasma than the capacitive coupling technique using a capacitive electrostatic field. A typical plasma etcher uses an additional electric field capacitively coupled to the substrate to increase ion energy.

Inductively coupled plasma sources typically use an antenna wound in circular spiral shape with an input terminal for receiving electromagnetic power at one end of the antenna and an output terminal for grounding at the other. This type of antenna induces a large potential difference between input and output terminals resulting in strong electric fields. Ions and electrons gaining energy through the interaction with these fields cause non-uniformity in the spatial energy distribution of plasmas which adversely impacts process results.

Hence, there is a need in the art for a system or technique for uniformly coupling electromagnetic energy for inductive generation of uniform plasmas.

### SUMMARY OF THE INVENTION

The need in the art is addressed by the antenna of the present invention. The inventive antenna is adapted to apply a uniform electromagnetic field to a volume of gas and includes an array of radiating elements with input terminals for receiving electrical energy into each radiating element and output terminal for grounding. The inventive antenna includes an array of radiating elements in the shape of circular, semicircular or rectangular loops connected in parallel.

In the illustrative embodiment, the antenna has three radiating elements. Each radiating element includes a conductor wound in a single turn circle with the same diameter. The input terminal of the second element is rotated 120° counterclockwise from the first and the input terminal of the third is rotated counterclockwise by 120° from the second. The ground terminal of each radiating element is located in the same manner as the input terminal.

The inventive antenna is adapted for use in a plasma processing system comprising a vacuum chamber, a gas disposed within the vacuum chamber, a dielectric tube disposed on the vacuum chamber, and a power circuit. The power circuit includes a source of radio frequency (RF) power, a switch and an impedance matching circuit. The impedance matching circuit efficiently couples power from the RF supply to the antenna.

The inventive antenna provides uniform coupling of electromagnetic power by spreading out high potential input terminals and ground terminals evenly along the circumference of a process tube, therefore resulting in uniform plasma density and energy across the entire substrate surface under a wide range of processing conditions.

### BRIEF DESCRIPTION OF THE DRAWINGS

FIG. 1 is a schematic sectional view of an illustrative embodiment of an inductively coupled plasma reactor implemented in accordance with the teachings of the present invention.

FIG. 2 is an illustrative embodiment of an antenna configuration adapted for use with the plasma reactor of FIG. 1 in accordance with the teachings of the present invention.

FIG. 3 is a schematic diagram of the antenna coils illustrating even distribution of input/output nodes in accordance with the teachings of the present invention.

FIG. 4 is a top view of the first antenna coil of FIG. 3.

FIG. 5 is a top view of the second antenna coil of FIG. 3.

FIG. 6 is a top view of the third antenna coil of FIG. 3.

### DESCRIPTION OF THE INVENTION

Illustrative embodiments and exemplary applications will now be described with reference to the accompanying drawings to disclose the advantageous teachings of the present invention.

While the present invention is described herein with reference to illustrative embodiments for particular applications, it should be understood that the invention is not limited thereto. Those having ordinary skill in the art and access to the teachings provided herein will recognize additional modifications, applications, and embodiments within the scope thereof and additional fields in which the present invention would be of significant utility.

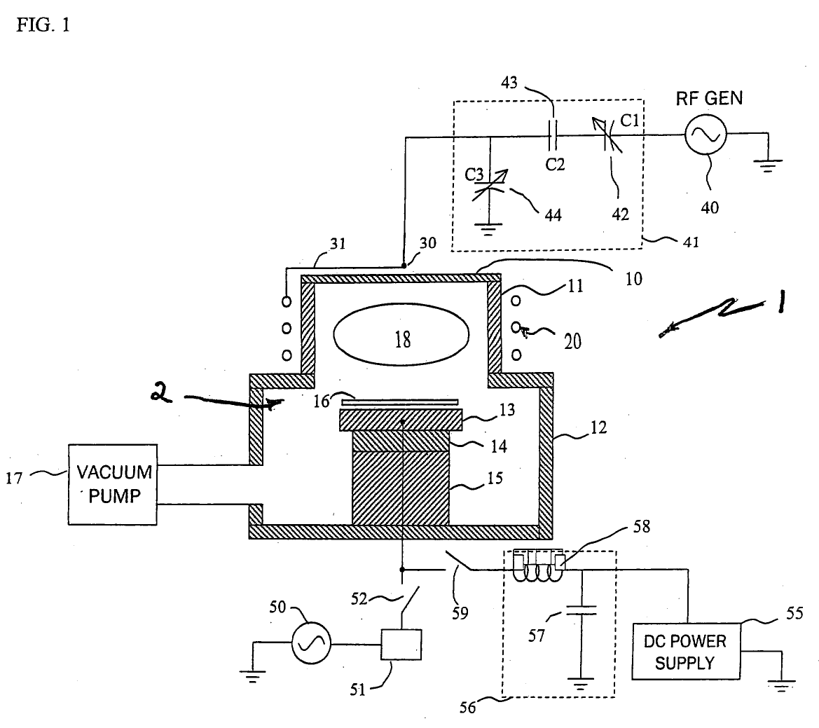

FIG. 1 is a schematic sectional view of an inductively coupled plasma reactor in accordance with an illustrative embodiment of the present invention. The system is designed for plasma processes such as etch and plasma CVD. As shown in FIG. 1, the system consists of a plasma source 18 and a process chamber 12 for plasma generation and wafer processing. Plasma source 18 is made of a dielectric tube 11, an antenna 20, and a gas injector 10. Process gases are injected through the gas injector 10 to the process chamber 12. The system operates at low pressure typically around mTorr range by using a vacuum pump 17. RF bias power is provided by a supply 50. This allows for RF bias power to be applied to control the ion energy in the plasma independently from an RF power source 40. Plasma 18 is generated by an inductively coupled electric field produced by an antenna 20.

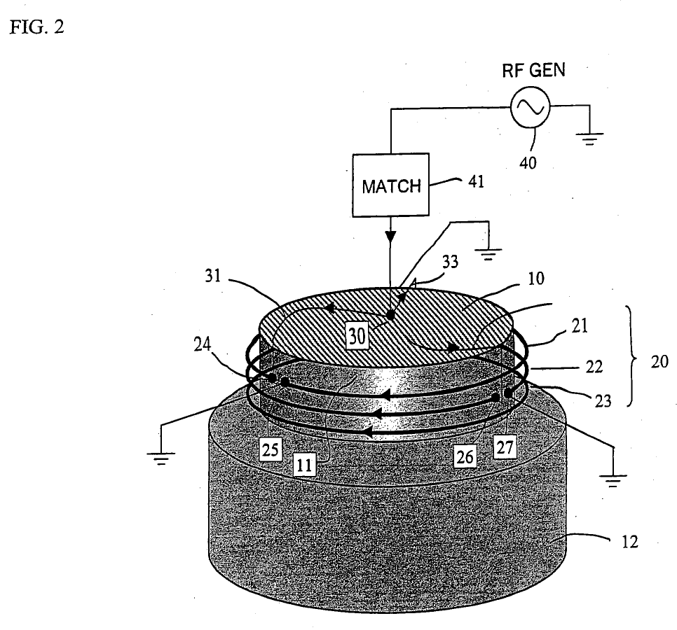

FIG. 2 shows an illustrative embodiment of the antenna of the plasma reactor in accordance with the teachings of the present invention. The antenna 20 consists of multiple inductive parallel coils 21, 22 and 23 wrapped around a cylindrical dielectric tube 11. The present invention is not limited to the shape of the dielectric tube. Other shapes may be used without departing from the scope of the present teachings.

In a conventional inductive antenna, a spiral coil with multiple turns is wrapped around a plasma generation chamber. Typically, one end of the inductive coil is connected to an RF power source and another end of the coil is connected to system ground. Therefore, there is only one RF input and one ground output in the continuous spiral coil. In that case, because the total coil length is large, transmission line properties of the induction coil result in voltage and current standing waves along its length. The variations in current with position along the coil lead to asymmetries in the induced electromagnetic fields, which, in turn, can lead to asymmetries in the power density of plasma and non-uniformity in the processing of components.

The inventive antenna 20 includes an array of radiating elements (coils) in the shape of circular, semicircular or rectangular loops connected in parallel. In the illustrative embodiment, the antenna has three radiating elements. Each radiating element includes a conductor wound in a single turn circle with the same diameter and preferrably, each inductive coil has only a single turn or less in order to reduce the transmission line effect. That is, in the best mode, each coil has a single turn or less to reduce the total inductance of the coil. Nonetheless, those skilled in the art will appreciate that the present teachings are not limited to the number of coils or the number of turns thereof.

The coils 21, 22, and 23 are arranged in parallel around the plasma generation reactor 11. Three different input nodes 24, 26, and 28 are provided for receiving RF energy and three different output nodes 25, 27, and 29 are provided for ground, respectively.

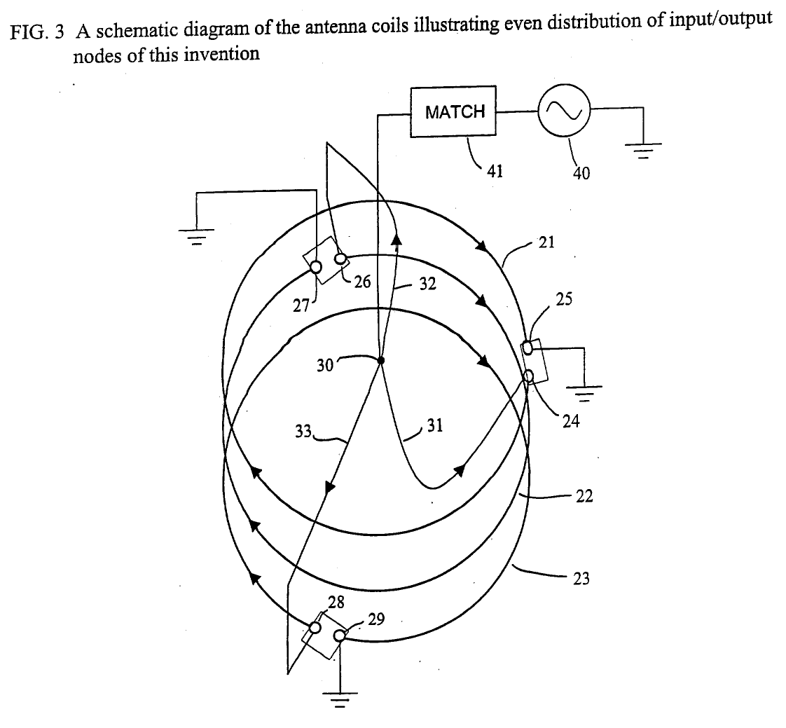

FIG. 3 is a schematic diagram of the antenna coils illustrating the even distribution of input/output nodes in accordance with the teachings of the present invention. Each antenna coil of single-turn loop 21, 22 and 23 is provided with a common RF power generator 40 connection via its own RF input nodes 24, 26, and 28 and a connection to ground via output nodes 25, 27, and 29, respectively. An RF impedance match network 41 is connected in series between the RF power generator 40 and a common RF input node 30 for the three antenna coils 21, 22, and 23.

The first coil 21 has an input node 24 for receiving RF energy at one end and an output node 25 connected to ground at the other end. Since it has a circular turn, the two nodes 24 and 25 are close to each other. The second 22 and third 23 coils are configured by 120 deg and 240 deg rotation from the position of the input and output nodes 24 and 25 of the first coil 21 for even distribution. Therefore, the present invention improves the power deposition symmetry as well as the ion flux uniformity on the surface of wafer 16 (FIG. 1). In the best mode, the antenna rotation is equal to 360 divided by the number of turns thereof. Nonethesless, those skilled in the art will appreciate that the present invention is not limited thereto. Other antenna rotations and turns ratios may be used without departing from the scope of the present teachings.

The RF current direction along the antenna coils 20 is same for all three loops 21, 22, and 23. The connections 31, 32, and 33 for RF power 40 from the common RF input point 30 to each RF input nodes 24, 26, and 28 of three coils 20 have same length to avoid destructive interference among the coil currents. It can be implemented by two methods to make the same length of the RF connection. First, three connections 31, 32, and 33 of same length are wired with curved shape to make same length from the common input point 30 located at the center of the loops 20 to each three different RF input nodes 24, 26, and 28 of coil loops 20.

Second, three connectors with linear shape are wired from the common input point located at a point off-centered to each RF input nodes. Since all coil loops 20 have only single turn, the three output nodes 25, 27, and 29 for ground at the other end in the loops 20 are also mounted with same configuration as the RF input nodes 24, 26, and 28 with 120 degree differences.

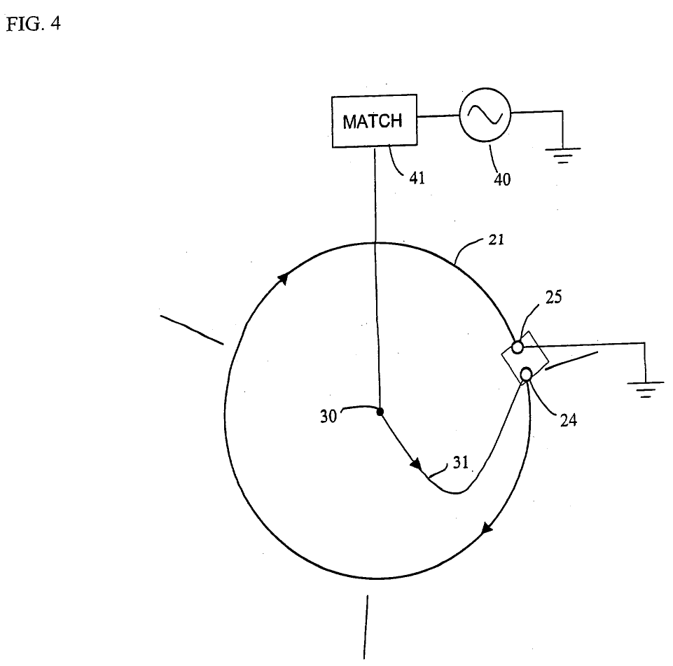

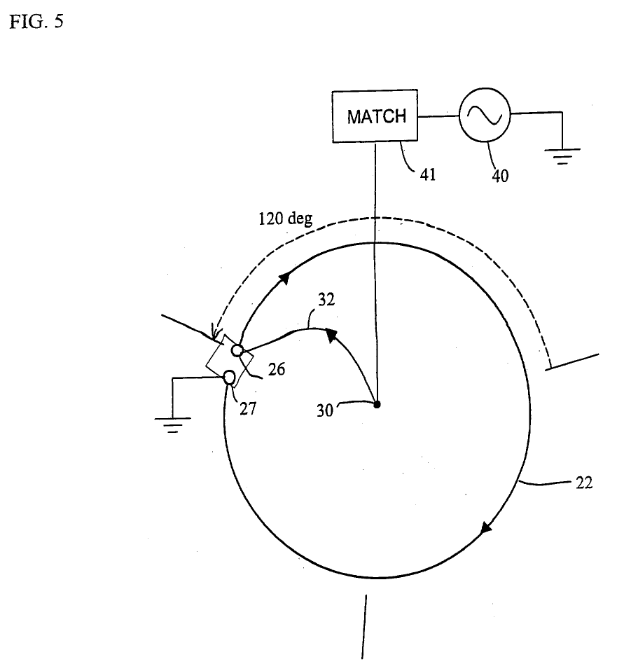

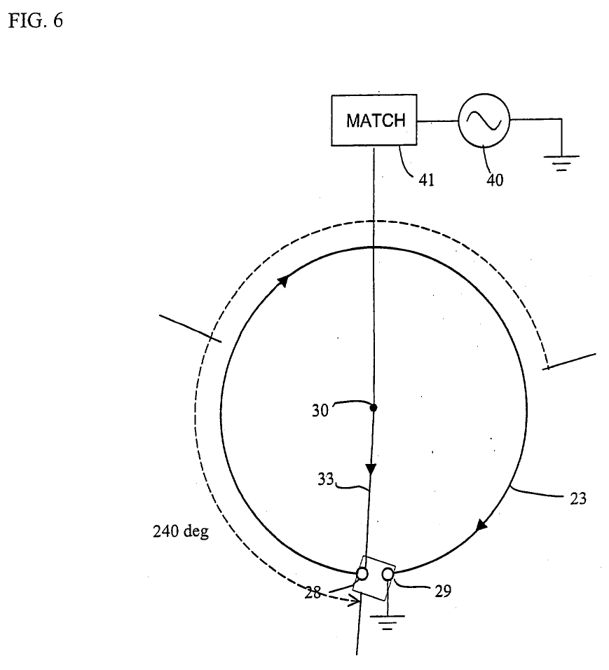

In FIGS. 4, 5, and 6, top views of each of the coil loops 20 are shown with 120 degree angle differences for the input/output nodes thereof. The advantage of this method of evenly distributing the RF input nodes 24, 26, and 28 and ground nodes 25, 27, and 29 of each coil loops 20 is that it minimizes the potential unbalance along the antenna coil 20. Usually, the potential difference between the RF input and output nodes is smaller in the coil with shorter length.

However, some potential difference between the input/output nodes may not be avoided even though a single-turn coil is used. Thus, if the antenna nodes are mounted using a common input and a common output arrangement such as superposition, the potential difference between each input/output nodes will be overlapped and enhanced. This typically results in non-uniform plasma in the wafer process.

However, by the inventive method of using even distribution, if the three pairs of nodes 24/25, 26/27, and 28/29 of each of the coil loops 20 are distributed evenly, the unbalance of total potential can be minimized to get uniform plasma and process results across the entire wafer 16 surface.

The coils are conductive materials such as copper or other suitable conductor. Those of ordinary skill in the art may choose the diameters and number of turns of the coils to suit a particular application. In the best mode, cooling water is flowed through the antenna coils 20. This should allow the coils to deliver up to 2500W of RF power to a plasma 18.

Returning to FIG. 1, the output of the RF generator 40 is connected to the antenna coils 20 via the matching network 41. In the illustrative embodiment, the matching network includes two series capacitors 42 and 43 (C1 and C2) and a capacitor 44 (C3) connected to ground. Two capacitors 42 and 44 are variable capacitors and the third capacitor 43 is a shunt capacitor with a fixed capacitive value.

In the case of a three single-turn antenna with 12 inch diameter, the following capacitance values may be used to tune the RF source: C1=80 pF, C2=50 pF, and C3=440 pF. This capacitive matching network may limit reflected power to a level within 2% of forward powers up to 2500W.

In conventional RF systems, ion energy and flux are linked, and cannot be controlled independently. However, the mean ion bombarding energy and its energy distribution should be controlled independently of the ion and neutral fluxes to tailor the film properties such as stress, composition, refractive index, crystallinity, and topography. In the plasma etching, ion energy also needs to be controlled to control etch rate, optimize selectivity, and minimize the device damage. Therefore, it is very important for the plasma process to offer better control of ion energy and couple it from ion flux control.

As shown in FIG. 1, the plasma reactor of this invention contains two auxiliary power sources 50 and 55. Each bias can be selected using switches 52 and 59. The substrate holder, chuck 13, has an anodized surface and it is mounted on chamber bottom 15. Insulation 14 is supplied between chuck 13 and the chamber bottom 15 to isolate the chuck 13 from the chamber ground. The first bias is the “RF bias” power 50 which is applied to the chuck 13 to control ion bombardment energies onto the substrate 16 surface. Independent control over ion bombarding energy can be achieved by biasing a second RF source 50 on the substrate chuck 13. The RF bias power 50 is applied to the substrate chuck 13 to control the energy of ions bombarding the substrate 16 surface. Thus, the present invention provides a wider process window for etching such as etch rate, etch profile, and selectivity.

The second bias is “positive DC voltage”. This bias can be used for film deposition by plasma chemical vapor deposition (CVD). A “Low Pass Filter” 56 is connected in series between the DC power supply 55 and the chuck 13 to supply DC potential without interference with RF energy. Positive DC potential is applied to the anodized chuck 13 to control the flux of positive ions from the plasma 18 to the wafer 16. This positive DC bias modifies the chuck 13 potential near the wafer 16, and the electric field generated by the biased chuck 13. The DC bias has a strong influence on the charged particles impinging on the wafer 16 surface. Applying positive bias to the chuck 13 leads to a decrease of ion flux, which improves the quality and surface roughness of the film by CVD process.

In general, the plasma consists of electrons, ions, neutral radicals, and neutral atoms or molecules. A decrease of ion flux implies that the contribution of neutral radicals of plasma become larger than that of energetic ions. Therefore, the proper control of ion energy and flux can be an effective way to suppress plasma induced damage and film stress.

Also, since the ion energy can be minimized, the reactor of this invention can be applied to the plasma process for damage-sensitive devices such as GaAs or InP compound semiconductor devices. One advantage of this invention is that high plasma densities can be produced with low or controlled ion energy. An RF bias 50 on the substrate 16 is used to draw ions to the substrate 16 at the desired impact energy. Thus, optimum ion energy can be selected—one that is high enough to produce anisotropic etching, but not too high as to cause lattice damage or impurity implantation. Therefore, the plasma reactor 11, 12 of this invention can be applied to the plasma processing of fabrication of III-V semiconductor (GaAs- or InP-based HBT's and HEMT's) and photonic devices (nitride based photonic devices and quantum well lasers). Low ion energy as well as controllability of the ion energy is an essential requirement in the fabrication of these devices.

Thus, the present invention has been described herein with reference to a particular embodiment for a particular application. Those having ordinary skill in the art and access to the present teachings will recognize additional modifications, applications and embodiments within the scope thereof.

It is therefore intended by the appended claims to cover any and all such applications, modifications and embodiments within the scope of the present invention.

Accordingly,

What is claimed is:

1. An inductively-coupled plasma reactor comprising:
reactor chamber adapted to retain a plasma;
a power source; and
plural inductive antenna coils connected in parallel between said power source and ground and disposed at least partially around said chamber.

2. The invention of claim 1 wherein each of said coils has a single turn or less.

3. The invention of claim 2 wherein each of said coils is disposed relative to each other to effect and even distribution of energy from said source.

4. The invention of claim 3 wherein the input and output nodes of the second coil are offset in a first direction by 120 degrees relative to said first coil and the input and output nodes of said third coil are offset by 120 degrees relative to said second coil.

5. The invention of claim 1 wherein said source is a source of radio frequency (RF) energy.

6. The invention of claim 1 further including a matching network connected between said power source and said antenna coils.

7. The invention of claim 1 wherein the matching network includes two series capacitors and one parallel capacitor connected to ground.

8. The invention of claim 1 further including an electrically isolated chuck.

9. The invention of claim 8 further including a bias RF power supply connected to said chuck.

10. The invention of claim 8 further including a DC power supply connected to said chuck.

11. An inductively-coupled plasma reactor comprising:
reactor chamber adapted to retain a plasma;
an RF power source; and
plural inductive antenna coils connected in parallel between said power source and ground and disposed at least partially around said chamber, each of said coils having a single turn or less and being disposed relative to each other to effect and even distribution of energy from said source.

12. The invention of claim 11 wherein the input and output nodes of the second coil are offset in a first direction by 120 degrees relative to said first coil and the input and output nodes of said third coil are offset by 120 degrees relative to said second coil.

13. The invention of claim 11 further including a matching network connected between said power source and said antenna coils.

14. The invention of claim 13 wherein the matching network includes two series capacitors and one parallel capacitor connected to ground.

15. The invention of claim 11 further including an electrically isolated chuck.

16. The invention of claim 11 wherein said RF power supply is connected to said chuck.

17. The invention of claim 11 further including a DC power supply connected to said chuck.

18. The invention of claim 11 wherein the reactor chamber has a dielectric tube window at the top plasma generation section and aluminum wall at the processing section.

19. The invention of claim 11 wherein the tube-type dielectric window is placed between antenna and plasma generation section.

20. A novel method for plasma processing a device including the steps of:
mounting the device within a chamber and
applying an electromagnetic field to the gas via an array of antenna elements disposed relative to the gas to generate a uniform distribution of the plasma.
